(19) United States
(12) Patent Application Publication
(10) Pub. No.: US 2024/0203913 A1
(43) Pub. Date: Jun. 20, 2024

(54) Method For Producing A Solder Contact Surface On A Chip By Producing A Sinter Paste Interface

(71) Applicant: PAC TECH - PACKAGING TECHNOLOGIES GMBH, Nauen (DE)

(72) Inventor: Matthias Fettke, Berlin (DE)

(21) Appl. No.: 18/532,793

(22) Filed: Dec. 7, 2023

(30) Foreign Application Priority Data
Dec. 15, 2022 (DE) 10 2022 133 386.8

(51) Int. Cl. H01L 23/00

(52) U.S. Cl. CPC H01L 24/03; H01L 24/05; H01L 24/13; H01L 2224/03312; H01L 2224/03318; H01L 2224/03505; H01L 2224/05124; H01L 2224/05639; H01L 2224/05644; H01L 2224/05647

(57) ABSTRACT

A chip comprising a non-conductive substrate layer and at least one conductor path disposed on the substrate layer, the solder contact surface being at least partially formed on the conductor path, and a method for producing the solder contact surface on the chip including the steps of: applying a sinter paste to a contact location at least partially located on the conductor path, the sinter paste comprising particles of at least one soft-solderable and conductive material and at least one solvent; and evaporating the solvent.

### CROSS-REFERENCE TO RELATED APPLICATIONS

This application claims priority to German Patent Application No. DE 10 2022 133 386.8 filed Dec. 15, 2022. The content of this application is hereby incorporated by reference as if set forth in its entirety herein.

The disclosure relates to a method for producing a solder contact surface on a chip, to a chip comprising a solder contact surface and to a use of a chip comprising a solder contact surface.

It is known from the state of the art to mechanically and/or electrically connect two or more electronic material components, in particular chips or other electronic components. A technique for connecting a chip to a contact conductor is known from DE 10 2015 103 779 A1. In a first step, a sinter paste is applied to a conductor path of a chip for this purpose and then a contact conductor is sintered onto the paste. However, the disadvantage of this method is that it only allows a chip to be connected to a contact conductor, but not a chip to be connected to any other component, in particular another chip.

A method for connecting two material components, for example two chips, by means of soldering is known from document DE 19 524 739 A1. The disadvantage of the disclosed method is that the application of a solderable contact layer on at least one, usually both, material component(s) is necessary to prepare the flip-chip mounting. This is due to the fact that the conductor paths on the material components are made of aluminum by default. However, aluminum has the disadvantage that soft soldering or low-temperature soldering is not possible. Aluminum can only be soldered at a temperature between 380° C. and 420° C. after complex preparatory work, the materials used for the components regularly being able to be heated up to only 175° C. It is therefore necessary to form an interface by providing a solder contact surface in order to enable soft soldering or low-temperature soldering. In the state of the art, these solder contact surfaces required for soldering are produced wet-chemically, galvanically or physically by sputtering. The disadvantage of these methods is that they are complex to prepare and manufacture and are costly and therefore unsuitable, especially for small quantities.

There is therefore a great need for a method for producing a solder contact surface on a chip and for a chip having a solder contact surface suitable for soft soldering. The manufacturing process should also be cost-effective. In addition, it should be easy to prepare and implement, so that it is economical even with a small number of chips to be produced and enables the provision of a cost-effective and solderable chip. At the same time, it should be quick and reliable to implement.

This object is attained in a surprisingly simple but effective manner by a method for producing a solder contact surface on a chip according to the teachings of main claim 1, by a chip comprising a solder contact surface according to the teachings of claim 10 and by a use of a solder contact surface in a soft soldering method according to claim 15.

According to the disclosure, a method for producing a solder contact surface on a chip is proposed, the chip comprising a non-conductive substrate layer and at least one conductor path disposed on the substrate layer, the solder contact surface being at least partially formed on the conductor path, and the method comprising the following steps:
a. applying a sinter paste to a contact location at least partially located on the conductor path, the sinter paste comprising particles of at least one soft-solderable and conductive material and at least one solvent; and
b. evaporating the solvent.

The basic idea of the disclosure is to form the solder contact surface by applying particles of the conductive and soft-solderable material by means of the sinter paste at a previously determined location intended for soldering, i.e., the contact location. When the sinter paste is applied, the particles are dissolved in the solvent and can therefore be applied in a simple manner known to the skilled person. The solvent is then evaporated so that the particles bond physically or chemically with the chip surface. Since the particles are made up of a soft-solderable material, subsequent or later soldering onto the formed solder contact surface becomes possible.

The chip with which the method is implementable comprises the substrate layer and the conductor path disposed on the substrate layer. The substrate forming the substrate layer is preferably a plastic material or a ceramic material, in particular silicon, glass or a thermoplastic material, preferably polyethylene naphthalate. The conductor path serves to connect in an electrically conductive manner the components connected or to be connected to the chip, in particular electronic components or semiconductor components. In the scope of the disclosure, the conductor path and/or the contact location is preferably formed by means of a non-solderable material, for which reason the production of a solder contact surface is required for the application of further components by means of soldering.

To enable a conductive contact between the component soldered onto the chip and the conductor path of the chip, the solder contact surface is formed on a contact location at least partially located on the conductor path. The contact location is the area of the chip which is intended for the subsequent contacting by means of soldering. The fact that the contact location and thus the subsequent solder contact surface are located at least partially on the conductor path and that the solder contact surface is formed from particles of at least one soft-solderable and conductive material means that a conductive connection with the conductor path is formed by the solder contact surface. In other words, by producing the solder contact surface on a non-solderable contact location of a conductor path of a chip, this chip can be made accessible to a soft soldering process.

It is conceivable that, in addition to the solvent and the particles made up of at least one soft-solderable and conductive material, the sinter paste contains at least one further additive, in particular additives for increasing the viscosity, for preventing agglomeration, stabilizers, carriers and/or binders. In particular, the carrier material and/or the solvent is an alcohol solution, a glycol solution and/or an epoxy resin, which enable particularly easy processing and evaporate at low temperatures. Additives for increasing the viscosity are in particular ethanol or ethanolamine. An increased viscosity simplifies applying the sinter paste, a sinter paste having increased viscosity also being known as sinter ink. Other suitable additives are known to the skilled person. Particularly preferably, the proportion of particles in the sinter paste is between 50% and 90% by volume.

The term “sinter paste” refers to a suspension, the suspension comprising the particles made up of at least one soft-solderable and conductive material and the solvent.

The term “non-conductive substrate layer” refers to a material layer on which the chip is constructed and which has a conductivity of less than or equal to 10⁻⁸ S/cm.

The term “conductive material” refers to a material which has a conductivity greater than or equal to 10⁴ S/cm.

The term “soft soldering” refers to a method in which two or more parts are materially bonded by means of a liquefied solder, part of the solder diffusing into the material of the parts to be joined to produce the material bond. Soft soldering is characterized by the melting point of the solder, which is below 450° C., but can also be significantly lower, in particular below 175° C., depending on the solder used.

The term “soft-solderable material” refers to a material from which a component or part of a component is made, the component or part of the component being able to be joined to another component or part of another component made of the same or another soft-solderable material using the technique of soldering by means of a soft solder.

Advantageous embodiments of the disclosure, which can be realized individually or in combination with each other, are shown in the dependent claims.

Particularly preferably, the sinter paste in step a. is applied by means of selective dispensation via a dispenser. In this manner, the solder contact surface can be applied to the chip at any desired location with little effort using small amounts of sinter paste, making the method cost-effective and quick to use.

In a preferred embodiment, the selective dispensation is the aerosol jet application. The aerosol jet application enables particularly small and therefore preferred sizes of the droplets or masses to be applied, which are adapted to the requirements in the preparation of chips for further processing. This allows particularly fine structures to be produced with pinpoint accuracy, which is particularly advantageous when applying the sinter paste on the chip, as the solder contact surface can be designed finely and precisely. In addition, the aerosol jet application also enables the construction of three-dimensional structures and the targeted application of the sinter paste almost independently of the surface structure of the substrate owing to the possibility of selective and additive material application. In particular, an application of the sinter paste by means of aerosol jetting in conjunction with laser sintering for vaporizing the solvent of the sinter paste and a separate application of solder deposits, in particular solder balls, for forming a solder joint on the solder contact surface allows a targeted three-dimensional structure of the solder contact surface and the solder joint to be formed on the solder contact surface. For laser sintering enables selective energy input into the sinter paste, and the separate application of solder deposits enables the targeted, selective application of the solder required to produce a solder joint. Thus, the masks or stencils known from the prior art are no longer necessary for applying the sinter paste and for forming the solder contact surface and for producing a solder connection on the solder contact surface. Indeed, the method according to the disclosure can be used universally and flexibly.

Alternatively, three-dimensional structures can also be constructed by applying the sinter paste using inkjetting.

However, it is also conceivable that in step a. of the method the sinter paste is applied by means of printing, which enables high throughput rates and thus cost-effective manufacturing processes. Various printing processes can be used to apply the sinter paste, such as screen printing, stencil printing, laser transfer printing, pad printing or gravure printing.

In one embodiment of the method, it is conceivable that the evaporation of the solvent in step b. is carried out at least partially by means of sintering. This results in a particularly dense arrangement of the conductive and soft-solderable particles in the solder contact surface, meaning the electrical resistance of the solder contact surface is kept very low. As a result, the electrical connection of a component to the chip at the solder contact surface produced by a subsequent or later soft soldering process has a particularly high degree of efficiency. This means that the losses, in particular the heat losses which occur when current flows through the solder contact surface are particularly low. Particularly preferably, the evaporation of the solvent in step b. is carried out at least partially by means of laser sintering, with a laser being used for this purpose. Laser sintering has the advantage that it can be used in a selective, pinpointed and targeted manner and can therefore be used efficiently. The risk of damage to parts of the chip adjacent to the contact location is also prevented, particularly in the case of the relatively small structures found on a chip. Furthermore, depending on the requirements for the design of the solder contact surface, highly compacted zones, which have hardly any air inclusions, can be formed in the sinter paste by means of sintering using laser energy. As a result, the surface of the solder contact surface in particular can be made extremely mechanically resilient. Particularly preferably, the laser is an NIR laser (near infrared laser), which is preferably operated in a wavelength range from 780 nm to 1400 nm. It has proven to be advantageous if a laser energy of 10 mJ to 40 mJ is applied to sinter the sinter paste using laser energy. An energy input of 15 mJ to 30 mJ is preferred. Particularly good results with regard to the durability of the solder contact surface are achievable when applying a laser energy of 19 mJ to 24 mJ to sinter the sinter paste using laser energy. Most preferably, a laser energy of 19 mJ, 19.5 mJ, 20 mJ, 20.5 mJ, 21 mJ, 21.5 mJ, 22 mJ, 22.5 mJ or 23 mJ is applied to sinter the sinter paste using laser energy. Furthermore, it has proven to be advantageous to use a pulse laser to apply the laser energy, the pulse laser for sintering the sinter paste being operated by means of laser energy having a pulse duration in the range of 1 ms to 4 ms. Preferably, the laser is operated with a pulse duration of 2.1 ms, 2.2 ms, 2.3 ms, 2.4 ms, 2.5 ms, 2.6 ms, 2.7 ms, 2.8 ms, 2.9 ms or 3 ms. It is particularly preferred to operate the laser for sintering the sinter paste using laser energy having a pulse duration of 2.3 ms.

In particular, it is advantageous to sinter the sinter paste before the solvent has completely evaporated. In this manner, complete drying of the sinter paste prior to sintering, which is considered disadvantageous, can be prevented. Cracks can easily form on a completely solvent-free or dried sinter paste as a result of the drying process or movement, leading to an increased electrical resistance of the solder contact surface.

The term “laser sintering” refers to a method in which the energy required for sintering is generated by means of a laser.

It has been found to be advantageous for the evaporation of the solvent in step b. to be carried out at least partially in a furnace, in particular at a temperature in the range from 60° C. to 250° C. The heat treatment of a material is also known to the skilled person under the term “tempering”. Preferably, the tempering is carried out in a furnace for a period of 3 minutes to 10 minutes, particularly preferably for a period of 5 minutes, in order to at least partially evaporate the solvent contained in the sinter paste. Further preferred is the heating of the connecting partners and in particular of the sinter paste, for an at least partial evaporation of the solvent contained in the sinter paste, in a furnace at a temperature between 80° C. and 230° C. By maintaining the above-mentioned temperature ranges and duration, a particularly durable and easy-to-produce solder contact surface can be realized which does not damage the chip. It should be noted that, depending on the duration, the chip may not reach the temperatures prevailing in the furnace. It is also conceivable that the evaporation of the solvent in step b. is carried out at least partially in the furnace by means of sintering.

Moreover, it is conceivable that the evaporation of the solvent in step b. is carried out at least partially by means of contact heating, in particular by means of contact heating of the substrate layer. In particular, the contact heating can be carried out before, simultaneously with and/or after sintering as described elsewhere. Contact heating has the advantage that it can be used over a large area and thus the solvent can be evaporated almost simultaneously at all locations, thereby forming a homogeneous layer as a solder contact surface, the heat supply being able to be easily regulated and limited. The solvent can also be quickly and easily released into the surrounding air. Another advantage of contact heating is that the chip does not have to be placed in a furnace or a similar device. The simplest method of contact heating is to place the chip with the substrate layer on a heating element.

Furthermore, it is conceivable that the chip in step a. and/or in step b. is held by means of a clamping device. In particular, it is conceivable that the following step is carried out before or during step a. or after step a. and before step b:

### a1. Clamping the Chip Using a Clamping Device.

In particular, the chip can be held on a heating element for carrying out the contact heating described elsewhere. The positioning secured against unintentional displacement, as achieved by clamping by means of a clamping element, is also advantageous when applying the sinter paste and when sintering, in particular laser sintering, as described elsewhere, since this enables a precise arrangement of the sinter paste and/or a precise control by means of the laser. In addition to the known clamping elements which are applied to the workpiece, for example using clamping jaws or claws, a clamping element can also be a vacuum clamping element which fixates the chip by applying a vacuum.

It is also conceivable that before or during the evaporation of the solvent in step b., pressure is applied to the sinter paste by means of a pressure apparatus. This also achieves a particularly dense placement of the particles consisting of a soft-solderable and conductive material. As a result, the electrical connection of a component to the chip at the solder contact surface has a particularly high degree of efficiency, the connection being produced by a subsequent or later soft soldering process. This means that the losses, in particular the heat losses, which occur when current flows through the solder contact surface are particularly low.

The material of the particles comprised in the sinter paste applied in step a. is particularly preferably gold, silver, copper and/or a compound having a gold content, a silver content and/or a copper content. These materials meet the requirements of the disclosure and are both soft-solderable and conductive.

The term “compound having a gold content, a silver content and/or a copper content” refers to a chemical compound comprising at least one gold atom, one silver atom and/or one copper atom.

It is also conceivable that the particle size of the particles comprised in the sinter paste applied in step a. is smaller than 100 nm. With this particle size, an application via the selective dispensation described elsewhere is possible in a simple manner. Particles of this size also allow simple and uniform distribution of the particles in the sinter paste. Particularly preferably, the particle size is smaller than 95 nm, 90 nm, 85 nm, 80 nm, 75 nm, 70 nm, 65 nm, 60 nm, 55 nm, 50 nm, 45 nm, 40 nm, 35 nm, 30 nm, 25 nm, 20 nm, 15 nm or 10 nm.

It is presumed that the definitions and/or explanations of the above-mentioned terms apply to all aspects described below in this description, unless otherwise stated.

According to the disclosure, a chip is further proposed, the chip comprising a non-conductive substrate layer and at least one conductor path. The chip is characterized in that the chip comprises at least one solder contact surface disposed at least partially on the conductor path, the solder contact surface being produced by the method described elsewhere. The chip according to the disclosure has the advantage that other components are soldered to this chip by means of soft soldering, the chip being inexpensive, quickly and individually adaptable and producible.

A substrate of the substrate layer is particularly preferably made of silicon or glass or a thermoplastic material, preferably polyethylene naphthalate. A substrate made of glass preferably has a thickness of 0.8 mm, 0.9 mm, 1 mm, 1.1 mm or 1.2 mm. A substrate made of a thermoplastic material, preferably polyethylene naphthalate, preferably has a layer thickness of 35 μm, 40 μm, 45 μm, 50 μm, 55 μm, 60 μm or 65 μm, with a layer thickness of 50 μm being particularly preferred.

In an embodiment of the chip, it is conceivable that the solder contact surface has a length and/or width of at least 5 μm and/or at most 20 μm. In this context, the length and/or width of the solder contact surface refers to the dimensions of the length of the solder contact surface parallel to the chip surface. It should be noted that by applying the sinter paste and evaporating the solvent, a solder contact layer is formed, the surface of which forms the solder contact surface. The solder contact surface of the solder contact layer runs parallel to the surface of the chip. In addition to the length and width, which also determine the solder contact surface, the solder contact layer also has a thickness. A length and/or width of at least 5 μm and/or at most 20 μm of the solder contact surface creates a solder contact surface which is sufficiently large for the soft soldering process and at the same time takes up as little space as possible on the chip. The solder contact surface is preferably rectangular, but any other shape is conceivable. The width and/or length of the solder contact surface is particularly preferably at least 5.5 μm, 6.0 μm, 6.5 μm, 7.0 μm, 7.5 μm, 8.0 μm, 8.5 μm, 9.0 μm, 9.5 μm, 10.0 μm, 10.5 μm, 11.0 μm, 11.5 μm, 12.0 μm, 12.5 μm, 13.0 μm, 13.5 μm, 14.0 μm, 14.5 μm, 15.0 μm, 15.5 μm, 16.0 μm, 16.5 μm, 17.0 μm, 17.5 μm, 18.0 μm, 18.5 μm, 19.0 μm or 19.5 μm. Even more preferably, the length and/or width of the solder contact surface is at most 19.5 μm, 19.0 μm, 18.5 μm, 18.0 μm, 17.5 μm, 17.0 μm, 16.5 μm, 16.0 μm, 15.5 μm, 15.0 μm, 14.5 μm, 14.0 μm, 13.5 μm, 13.0 μm, 12.5 μm, 12.0 μm, 11.5 μm, 11.0 μm, 10.5 μm, 10.0 μm, 9.5 μm, 9.0 μm, 8.5 μm, 8.0 μm, 7.5 μm, 7.0 μm, 6.5 μm, 6.0 μm or 5.5 μm.

In one embodiment, the solder contact surface is made of gold, silver, copper and/or a compound having a gold content, a silver content and/or a copper content or comprises gold, silver, copper and/or a compound having a gold content, a silver content and/or a copper content. This is achieved by the sinter paste, which is described elsewhere, comprising particles of one or more of these materials. These materials meet the requirements of the disclosure and are both soft-solderable and conductive.

It is also conceivable that the conductor path comprises aluminum. In particular, the conductor path is made of aluminum, and in particular the conductor path is an aluminum contact. Aluminum is a material frequently used in chip manufacturing for forming conductor paths: however, aluminum has the disadvantage of not being able to be soft-soldered. Therefore, the application of a solder contact surface to a chip comprising an aluminum conductor is particularly advantageous, as the chip also becomes soft-solderable or provides a soft-solderable connection location.

It is also conceivable that a solder bump is disposed, in particular soldered, on the solder contact surface. By means of the solder bump, the flip-chip method described in the introduction, together with the associated advantages, is possible. In addition, the application of the solder bump can advantageously lead to post-sintering of the sinter paste and thus of the solder contact surface. For the renewed introduction of heat into the solder contact surface by the solder bump, in particular by soldering on the solder bump, leads to further evaporation of the solvent contained in the sinter paste and thus to a closer cross-linking of the solder contact surface.

Further according to the disclosure, a use of the solder contact surface in a soft-soldering method is proposed, the solder contact surface being produced by the method described elsewhere. The soft-soldering method is particularly preferably part of a flip-chip method. Owing to the solder contact surface, soft-soldering of the chip becomes possible in the first place, as aluminum conductor paths or aluminum contacts are generally used for chips. However, aluminum cannot be soft-soldered. Therefore, a chip treated according to a method described elsewhere can be used advantageously in a soft-soldering method.

Further details, features and advantages of the disclosure can be derived from the following description of the preferred exemplary embodiment in conjunction with the independent claims. The corresponding features can be realized individually or in combination with one another. The disclosure is not limited to the exemplary embodiment. The exemplary embodiment is shown schematically in the FIGURES. Identical reference numerals in the individual FIGURES denote identical or functionally identical elements or elements which correspond to each other in terms of their function.

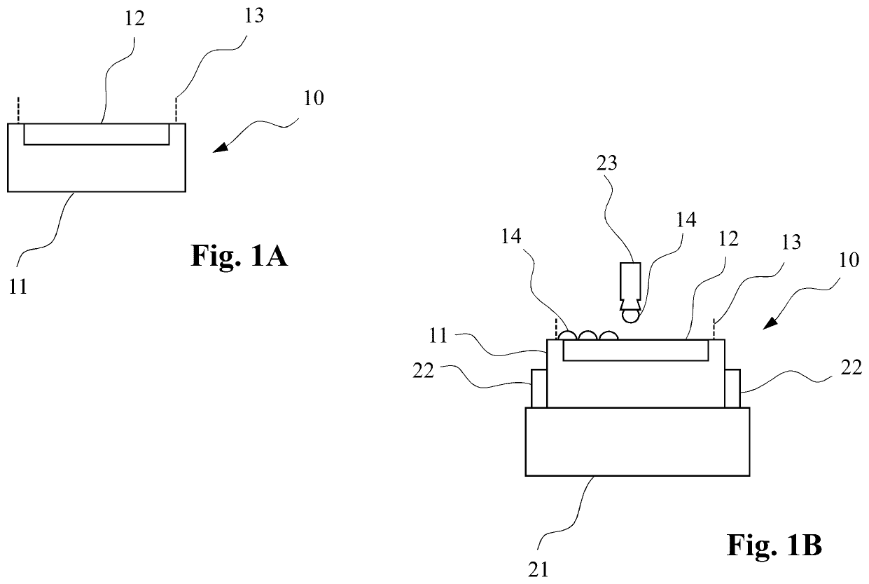

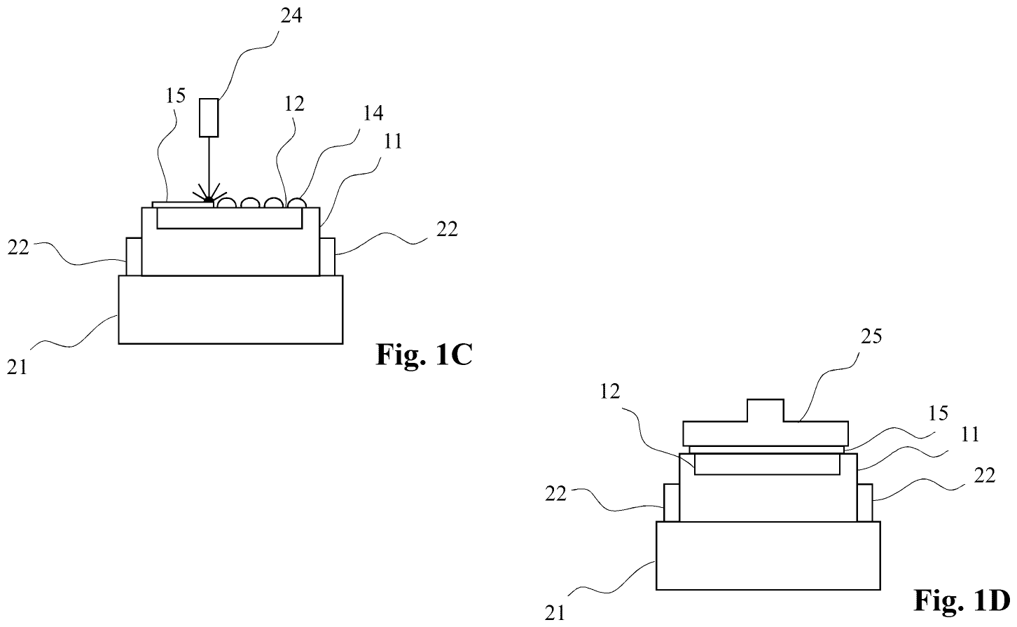

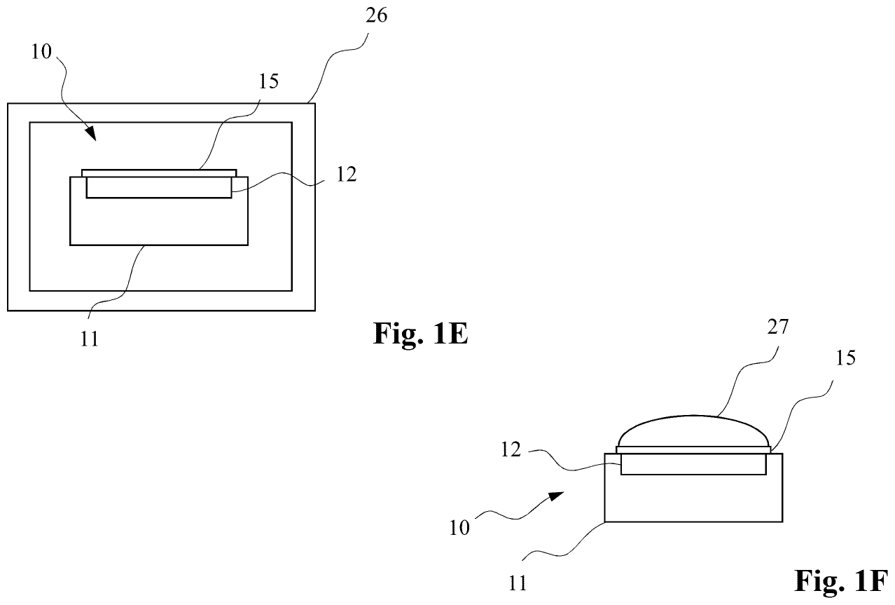

FIG. 1A to FIG. 1F, in a side view, show individual steps of the method according to the disclosure for producing a solder contact surface and the use of the solder contact surface according to the disclosure. The figures are merely schematic representations. In particular, the proportions of the individual components and tools are not shown in the correct proportions.

FIG. 1A shows a conventional chip 10 from the prior art. The chip 10 comprises a non-conductive substrate layer 11, on which and into which a conductor path 12 made of aluminum is placed. FIG. 1A shows a side view of the chip 10. A contact location 13 has already been marked on the substrate layer, on which contact location 13 a solder contact surface 15 (see FIG. 1D and FIG. 1E) is to be created at a later stage.

FIG. 1B shows the chip 10 having the non-conductive substrate layer 11 and the conductor path 12, the chip 10 having the substrate layer 11 having been placed on a heating element 21. To prevent the chip 10 from shifting, the chip 10 is held on the heating element 21 by clamping elements 22. A dispenser 23 dispenses drops of a sinter paste 14 onto the contact location 13, at least part of the conductor path 12 being covered with the sinter paste 14. The heating element 21 heats the substrate layer 11, heat passing through the chip 10 and partially evaporating the solvent in the sinter paste 14.

FIG. 1C shows the chip 10 having the non-conductive substrate layer 11 and the conductor path 12, the sinter paste 14 having been completely dispensed. A laser 24 sinters the sinter paste 14 and evaporates the solvent contained in the sinter paste 14 in addition to the heat emitted by the heating element 21. This results in a densely packed and continuous solder contact surface 15. The chip 10 is still held in place by the clamping elements 22.

FIG. 1D shows the chip 10 having the non-conductive substrate layer 11 and the conductor path 12, the solder contact surface 15 being pressurized by means of a pressure apparatus 25. The pressure further compacts the sinter paste 14 (see FIGS. 1B and 1C), while the heating element evaporates the solvent contained in the sinter paste 14. The chip 10 is held by the clamping elements 22.

FIG. 1E shows the chip 10 having the substrate layer 11 and the conductor path 12, the chip 10 having been placed in a furnace 26 for residue-free evaporation of the solvent. It can be seen that the finished solder contact surface 15 is disposed on the conductor path 12. Since the solder contact surface 15 is made of soft-solderable and conductive material, a further component (not shown) can be attached to the solder contact surface 15 by means of a soft-soldering method, an electrically conductive connection existing between the conductor path 12 and the further component.

FIG. 1F shows the chip 10 having the non-conductive substrate layer 11, the conductor path 12 and the solder contact surface 15. In order to use the chip 10 having the solder contact surface 15 in accordance with the disclosure, a solder bump 27 is disposed on the solder contact surface 15 in preparation for the flip-chip method. In the course of applying the solder bump 27, the solder contact surface 15 is reheated, which leads to further evaporation of the solvent and a closer cross-linking of the solder contact surface 15.

1. A method for producing a solder contact surface on a chip, the chip comprising a non-conductive substrate layer and at least one conductor path disposed on the substrate layer, the solder contact surface being at least partially formed on the conductor path, the method comprising the following steps:
a. applying a sinter paste to a contact location at least partially located on the conductor path, the sinter paste comprising particles of at least one soft-solderable and conductive material and at least one solvent; and
b. evaporating the solvent.

2. The method according to claim 1,
wherein the application of the sinter paste in step a. is carried out by means of selective dispensation via a dispenser.

3. The method according to claim 2,
wherein the selective dispensation in step a. is carried out by means of an aerosol jet application.

4. The method according to claim 1,
wherein the evaporation of the solvent in step b. is carried out at least partially by means of sintering, in particular by means of laser sintering via a laser.

5. The method according to claim 1,
wherein the evaporation of the solvent in step b. is carried out at least partially in a furnace.

6. The method according to claim 1,
wherein the evaporation of the solvent in step b. is carried out at least partially by means of contact heating.

7. The method according to claim 1,
wherein the chip in step a. and/or in step b. is held by means of a clamping element.

8. The method according to claim 1,
wherein pressure is applied on the sinter paste by means of a pressure apparatus before or during the evaporation of the solvent in step b.

9. The method according to claim 1,
wherein the material of the particles comprised in the sinter paste applied in step a. is gold, silver, copper and/or a compound having a gold content, a silver content and/or a copper content.

10. The method according to claim 1,
wherein the particle size of the particles comprised in the sinter paste applied in step a. is less than 100 nm.

11. A chip, comprising a non-conductive substrate layer, at least one conductor path and at least one solder contact surface disposed at least partially on the conductor path, obtained via the method according to claim 1.

12. The chip according to claim 11, wherein
the solder contact surface has a width and/or a length of at least 5 μm and/or maximally 20 μm.

13. The chip according to claim 11, wherein
the solder contact surface is made of gold, silver, copper and/or a compound having a gold content, a silver content and/or a copper content or comprises gold, silver, copper and/or a compound having a gold content, a silver content and/or a copper content.

14. The chip according to claim 11,
wherein
the conductor path comprises aluminum.

15. The chip according to claim 11,
wherein
a solder bump is disposed on the solder contact surface.

16. A use of a solder contact surface in a soft-soldering method, the solder contact surface being produced by the method according to claim 1.

17. The use according to claim 16,
wherein
the soft-soldering is part of a flip-chip method.

18. The method of claim 1, wherein the evaporation of the solvent in step b. is carried out at a temperature ranging from 60° C. to 250° C.

19. The method according to claim 1, wherein the evaporation of the solvent in step b. is carried out by means of contact heating of the substrate layer via placement on a heating element.

20. The chip according to claim 15, wherein the solder bump is soldered on the solder contact surface.
